(19) United States
(12) Patent Application Publication
(10) Pub. No.: US 2011/0312126 A1
(43) Pub. Date: Dec. 22, 2011

(54) METHOD FABRICATING A PHASE-CHANGE SEMICONDUCTOR MEMORY DEVICE

(75) Inventors: Byoung-Jae BAE, Hwaseong-si (KR); Byoung-Deog CHOI, Suwon-si (KR); Jeong-Hee PARK, Hwaseong-si (KR); Young-Kuk KIM, Seoul (KR); Jin-Ho OH, Seongnam-si (KR)

(73) Assignee: SAMSUNG ELECTRONICS CO., LTD., Suwon-si (KR)

(21) Appl. No.: 13/084,647

(22) Filed: Apr. 12, 2011

(30) Foreign Application Priority Data
Jun. 22, 2010 (KR) 10-2010-0059099

(51) Int. Cl. H01L 21/06; H01L 21/02

(52) U.S. Cl. 438/102; 438/382; 257/E21.068; 257/E21.004

(57) ABSTRACT

A method of fabricating a phase-change semiconductor memory device includes a plasma treatment of an electrode connected to a phase-change material pattern after a conductive layer used to form the electrode has been planarized in the presence of an oxidizing agent. The plasma is formed from a plasma gas having a molecular weight of 17 or less.

### CROSS-REFERENCE TO RELATED APPLICATION

This application claims priority from Korean Patent Application No. 10-2010-0059099 filed on Jun. 22, 2010, the subject matter of which is hereby incorporated by reference.

### BACKGROUND OF THE INVENTION

The present inventive concept relates to a method of fabricating semiconductor memory devices. Semiconductor memory devices may be classified as volatile devices that lose stored data in the absence of applied power and nonvolatile devices that retain stored data in the absence of applied power. Of nonvolatile memory devices, flash memory devices having a stacked gate structure are widely used. However, so-called “phase-change memory devices” have been suggested as a possible replacement for flash memory devices in certain applications.

Phase-change memory devices are generally characterized by the use of one or more phase-change material(s) that exhibit different electrical resistance according to defined materials states. However, these phase-change material(s) should exhibit a relatively narrow variation in resistance in order to ensure reliability of the constituent devices. To this end, a contact resistance between the phase-change material(s) and a contacting electrode should not vary outside a narrowly defined range.

To ensure that the contact resistance between the phase-change material(s) and the contacting electrode remains within this narrowly defined range, certain interface characteristics of the contacting electrode must be closely considered.

### SUMMARY OF THE INVENTION

Certain embodiments of the inventive concept provide a method of fabricating semiconductor devices including an electrode contacting phase-change material(s), wherein interface characteristics of the contacting electrode are notably improved.

In one embodiment, the inventive concept provides a method of fabricating a semiconductor device, the method comprising; forming an insulating layer on a semiconductor substrate, forming a contact hole in the insulating layer, forming a conductive layer comprising a first material, wherein the conductive layer comprises a first portion formed in the contact hole and a second portion formed on the insulating layer, planarizing the conductive layer in the presence of an oxidizing agent to remove the second portion of the conductive layer from the insulating layer, wherein a portion of the first material is changed to a second material by the presence of the oxidizing agent, such that a first electrode is formed by the first portion of the conductive layer comprising both the first material and the second material, plasma-treating the first electrode with a plasma formed from a plasma gas having a molecular weight of 17 or less to reduce a concentration of the second material in the first electrode relative to a concentration of the first material, and forming a phase-change material pattern on the first electrode.

In another embodiment, the inventive concept provides a method of fabricating a semiconductor device, the method comprising; forming a first insulating layer on a semiconductor substrate, forming a contact hole in the first insulating layer, forming a conductive layer comprising a first material, wherein the conductive layer comprises a first portion formed in the contact hole and a second portion formed on the first insulating layer, planarizing the conductive layer in the presence of an oxidizing agent to remove the second portion of the conductive layer from the first insulating layer, wherein a portion of the first material is changed to a second material by the presence of the oxidizing agent, such that a first electrode is formed by the first portion of the conductive layer comprising both the first material and the second material, forming a second insulating layer on the first insulating layer including the first electrode, forming a via hole in the second insulating layer to expose an upper surface of the first electrode, wherein forming the via hole in the second insulating layer causes the formation of a residual restacked film on the upper surface of the first electrode, plasma-treating the upper surface of the first electrode exposed through the via hole with a plasma formed from a plasma gas having a molecular weight of 17 or less to remove the residual restacked film and reduce a concentration of the second material in the first electrode relative to a concentration of the first material, and forming a phase-change material pattern on the first electrode.

In yet another embodiment, the inventive concept provides a method of fabricating a nonvolatile semiconductor memory device, the method comprising; forming a first mold layer on a semiconductor substrate, forming a first aperture in the first mold layer, and forming a word line in the first aperture, forming a second mold layer on the first mold layer including the word line, forming a second aperture in the second mold layer, and forming a vertical diode in the second aperture, forming a first interlayer insulating layer on the second mold layer including the vertical diode and forming contact hole in the first interlayer insulating layer, forming a conductive layer comprising a first material on the first interlayer insulating layer, wherein the conductive layer comprises a first portion formed in the contact hole and a second portion formed on the first interlayer insulating layer, planarizing the conductive layer in the presence of an oxidizing agent to remove the second portion of the conductive layer from the first interlayer insulating layer, wherein a portion of the first material is changed to a second material by the presence of the oxidizing agent such that the first electrode comprises both the first material and the second material, plasma-treating the first electrode with a plasma formed from a plasma gas having a molecular weight of 17 or less to reduce a concentration of the second material in the first electrode relative to a concentration of the first material, forming a phase-change material pattern on the first electrode, and forming a second electrode on the phase-change material pattern.

### BRIEF DESCRIPTION OF THE DRAWINGS

The above and other aspects and features of the present inventive concept will become more apparent by describing in detail exemplary embodiments thereof with reference to the attached drawings, in which:

FIG. 1 is a conceptual block diagram of a semiconductor device fabricated according to certain embodiments of the inventive concept;

FIG. 2 is a schematic circuit diagram of the semiconductor device fabricated according to certain embodiments of the inventive concept;

FIG. 3 is a cross-sectional view of a semiconductor device fabricated according to one embodiment of the inventive concept;

FIGS. 4 through 11 are related cross-sectional views respectively illustrating processes included within the method of fabricating semiconductor devices according to the embodiment of the present inventive concept described in relation to FIG. 3;

FIG. 12 is a cross-sectional view of a semiconductor device fabricated according to another embodiment of the inventive concept;

FIGS. 13 through 17 are related cross-sectional views respectively illustrating processes included in the method of fabricating the semiconductor device according to the embodiment of the inventive concept described in relation to FIG. 12;

FIGS. 18 through 24 are related cross-sectional views respectively illustrating processes included in a method of fabricating a semiconductor device according to yet another embodiment of the inventive concept;

FIG. 25 is a graph illustrating a difference in the relative concentrations of first and second materials in a surface of a first electrode both before and after plasma treatment of the first electrode; and

FIG. 26 is a graph illustrating a difference in the relative concentration of oxygen in the first electrode both before and after plasma treatment of the first electrode.

### DETAILED DESCRIPTION

Advantages and features of the present inventive concept and methods of accomplishing the same may be understood more readily by reference to the following detailed description of exemplary embodiments and the accompanying drawings. The inventive concept may, however, be embodied in many different forms and should not be construed as being limited to only the illustrated embodiments set forth herein. Rather, these embodiments are provided so that this disclosure will be thorough and complete and will fully convey the concept of the inventive concept to those skilled in the art, and the present inventive concept will only be defined by the appended claims.

Throughout the written description and drawings, like reference numbers and labels are used to denote like or similar elements. As used herein, the term “and/or” includes any and all combinations of one or more of the associated listed items.

As used herein, the singular forms “a”, “an” and “the” are intended to include the plural forms as well, unless the context clearly indicates otherwise. It will be further understood that the terms “comprises” and/or “made of,” when used in this specification, specify the presence of stated components, steps, operations, and/or elements, but do not preclude the presence or addition of one or more other components, steps, operations, elements, and/or groups thereof.

It will be understood that, although the terms first, second, third, etc., may be used herein to describe various elements, these elements should not be limited by these terms. These terms are only used to distinguish one element from another element. Thus, a first element discussed below could be termed a second element without departing from the teachings of the present inventive concept.

Embodiments of the inventive concept are described herein with reference to plan and cross-section illustrations that are schematic illustrations of idealized embodiments of the inventive concept. As such, variations from the shapes of the illustrations as a result, for example, of manufacturing techniques and/or tolerances, are to be expected. Thus, embodiments of the inventive concept should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

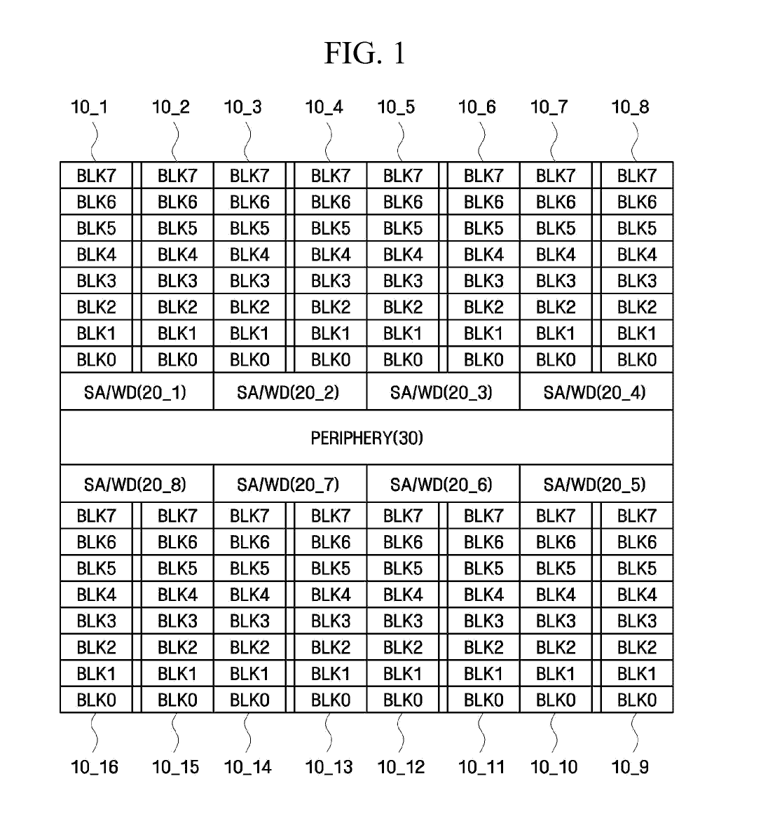

Hereinafter, certain methods of fabricating semiconductor devices according to embodiments of the inventive concept will be described with reference to FIGS. 1 through 24.

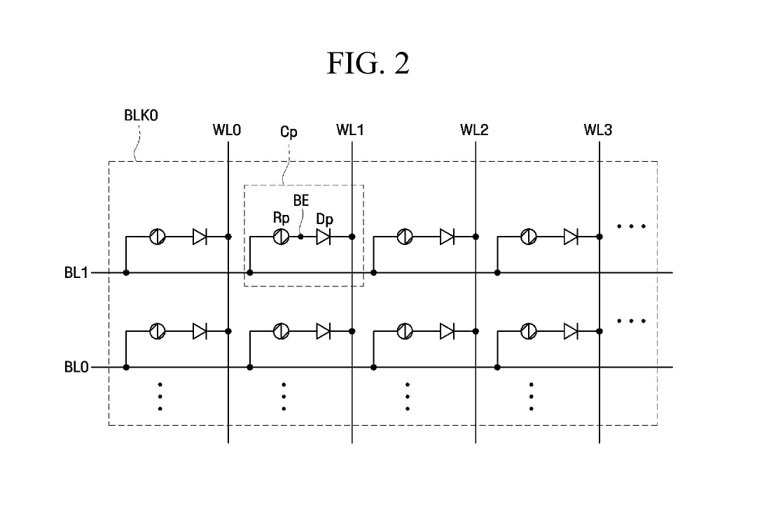

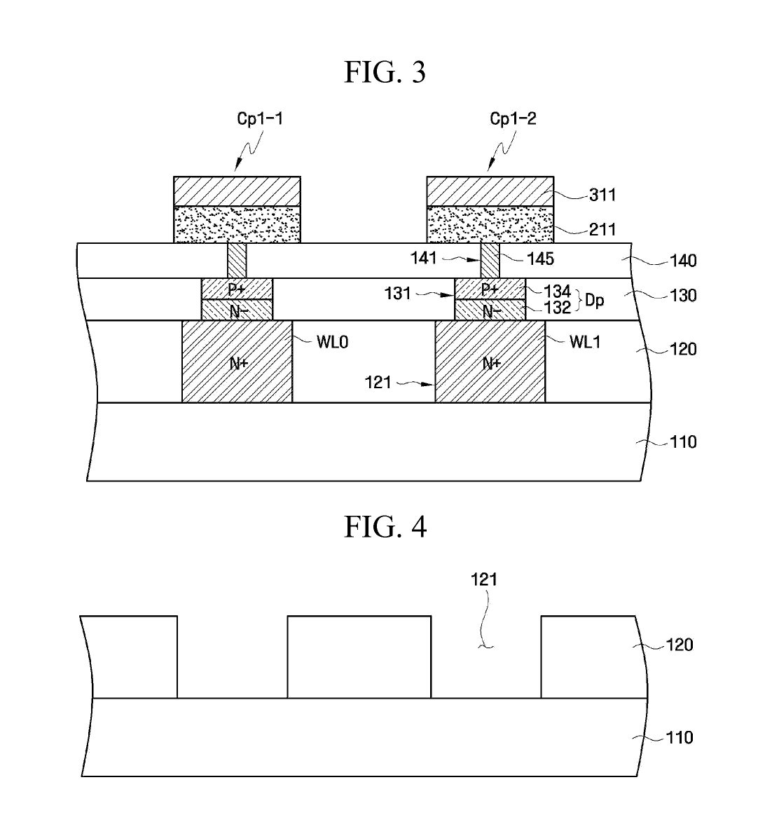

First, a semiconductor device fabricated according to exemplary embodiments of the present inventive concept will be described with reference to FIGS. 1 through 3. FIG. 1 is a conceptual block diagram of a semiconductor device fabricated according to certain embodiments of the inventive concept. FIG. 2 is a schematic circuit diagram of a portion of the semiconductor device that may be fabricated according to the certain embodiments of the inventive concept. FIG. 3 is a cross-sectional view of a semiconductor device fabricated according to one embodiment of the inventive concept.

Referring to FIG. 1, the semiconductor device comprises a plurality of memory banks 10_1 through 10_16, a plurality of sense amp and write drivers 20_1 through 20_8, and a peripheral circuit region 30.

Each of the memory banks 10_1 through 10_16 is sub-divided into a plurality of memory blocks BLK0 through BLK7, and each of the memory blocks BLK0 through BLK7 may include a plurality of nonvolatile memory cells arranged in a matrix of rows and columns. In the illustrated embodiment of FIG. 1, eight memory blocks are arranged in each memory bank. However, those skilled in the art will recognize that embodiment of FIG. 1 is only one example a many semiconductor memory device layouts that may be obtained according to various embodiments of the inventive concept.

Although not shown in detail in FIG. 1, a plurality of row decoders and a plurality of column decoders may be arranged to correspond to the memory banks 10_1 through 10_16 and designate rows and columns of nonvolatile memory cells to be read or written, respectively.

Each of the sense amp and write drivers 20_1 through 20_8 corresponds to two of the memory banks 10_1 through 10_16 and performs a read or write operation on corresponding memory banks. In certain embodiments of the inventive concept, each of the sense amp and write drivers 20_1 through 20_8 corresponds to two of the memory banks 10_1 through 10_16. However, the inventive concept is not limited to only this arrangement. For example, each of the sense amp and write drivers 20_1 through 20_8 may also correspond to one or four of the memory banks 10_1 through 10_16.

In the peripheral circuit region 30, a plurality of logic circuit blocks and a plurality of voltage generators are arranged to drive the row decoders, the column decoders, and the sense amp and write drivers 20_1 through 20_8.

Referring to FIG. 2, a portion of the memory block BLK0 shown in FIG. 1 is further illustrated and includes a plurality of nonvolatile memory unit cells Cp, a plurality of bit lines BL0 and BL1, and a plurality of word lines WL0 through WL3.

Each of the nonvolatile memory unit cells Cp is arranged at an intersection of one of the word lines WL0 through WL3 and one of the bit lines BL0 and BL1. The phase-change material within each one of the nonvolatile memory unit cells Cp may be placed in a crystalline or an amorphous state by application of a heating electrical current. That is, each of the nonvolatile memory unit cells Cp includes a phase-change element Rp which exhibits a different resistance for each material state (crystalline verses amorphous), and a vertical cell diode Dp which controls the application of electrical current through the phase-change element Rp. The phase-change element Rp may a combination of two elements such as GaSb, InSb, InSe, SbTe or GeTe, a combination of three elements such as GeSbTe, GaSeTe, InSbTe, SnSb₂Te₄ or InSbGe, or a combination of four elements such as AgInSbTe, (GeSn)SbTe, GeSb(SeTe) or Te₈₁Ge₁₅Sb₂S₂. In particular, GeSbTe, which is a combination of germanium (Ge), antimony (Sb) and tellurium (Te), may be mainly used as the phase-change element Rp. The phase-change element Rp included in each nonvolatile memory unit cell Cp according to embodiments of the inventive concept will be described in some additional detail hereafter.

As illustrated in FIG. 2, each phase-change element Rp is coupled to between a respective bit line BL0 and BL1 and a respective word line WL0 through WL3 through a corresponding vertical cell diode Dp. However, the inventive concept is not limited to only this particular configuration of elements and this connection structure. For example, each one of the phase-change elements Rp may be coupled to a respective word line WL0 through WL3, and each vertical cell diode Dp may be coupled to a respective one of the bit line BL0 and BL1.

An exemplary operation of a semiconductor device fabricated according to an embodiment of the inventive concept will now be described with reference to FIG. 2.

During a write operation, the phase-change element Rp is heated to a temperature higher than its melting temperature and is then quickly cooled. This heating and cooling sequence causes the phase-change element Rp to assume an amorphous state, which is commonly associated with a digital logic value of “1”. Alternatively, the phase-change element Rp is heated to a temperature higher than its crystallization temperature but lower than its melting temperature, maintained at this temperature for a predetermined period of time, and then cooled. This heat and cooling sequence causes the phase-change element Rp to assume a crystalline state, which is commonly associated with a digital logic value of “0”. To change the phase (i.e., the corresponding material state) of the phase-change element Rp, a write current of significantly high level is applied to the phase-change element Rp (i.e., a variable resistance material). For example, a write current of approximately 1 mA may be applied to reset the phase-change element Rp, and a write current of 0.6 to 0.7 mA may be applied to set the phase-change element Rp. The write current may be supplied from a write circuit (not shown) though one of the word lines WL0 through WL3 via the bit lines BL0 and BL1, the vertical cell diode Dp, and the phase-change element Rp.

During a read operation, a read current having a level that does not change the phase of the phase-change element Rp may be applied to the phase-change element Rp in order to “read” the stored data (i.e., determine the defined phase of the phase-change element Rp. The read current may be applied from a read circuit (not shown) through one of the word lines WL0 and WL1 via the bit lines BL0 through BL3, the vertical cell diode Dp, and the phase-change element Rp.

A semiconductor device according to an embodiment of the inventive concept will now be described with reference to FIG. 3. Referring to FIG. 3, a semiconductor device may be fabricated that includes a plurality of unit cells (e.g.,) Cpl-1 and Cpl-2. Each of the unit cells Cpl-1 and Cp2-1 may include a vertical cell diode Dp, a first electrode 145, a phase-change material pattern 211, and a second electrode 311.

A substrate 110 included in the semiconductor device may be a silicon substrate, a silicon-on-insulator (SOI) substrate, a gallium arsenic substrate, or a silicon germanium substrate.

A first mold layer 120 (as an example of one type insulating layer) is formed on the substrate 110. The first mold layer 120 may be made of SiOx such as FOX (Flowable OXide), TOSZ (Tonen SilaZene), USG (Undoped Silicate Glass), BSG (Boro Silicate Glass), PSG (Phospho Silicate Glass), BPSG (BoroPhospho Silicate Glass), PE-TEOS (Plasma Enhanced-Tetra Ethyl Ortho Silicate), FSG (Fluoride Silicate Glass), HDP (high density plasma), or the like.

A first aperture 121 is formed in the first mold layer 120 and is subsequently filled with conductive material forming one of the word lines WL0 and WL1. The first aperture 121 may extend vertically through the first mold layer 129 to the substrate 110. Accordingly, the word lines WL0 and WL1, each filling a respective first aperture 121, may be thought of as vertically extending upward from the substrate 110. However, those skilled in the art will recognize the term (and concept) of “vertical” is merely a relative orientation description given to clearly describe certain geometric relationships between elements of the illustrated embodiment. Thus, vertical may be relatively distinguished from lateral or horizontal. The word lines WL0 and WL1 may be formed from a conductive material having a defined conductivity type (e.g., an N type) that is the same as the semiconductor substrate 110. The concentration of first type conductivity impurities in the conductive material forming each of the word lines WL0 and WL1 may be, but is not limited to, 1×10¹⁹ atoms/cm³ or higher. In certain embodiments of the inventive concept, the conductive material forming the word lines WL0 and WL1 may be epitaxial layers. When the semiconductor substrate 110 is a mono-crystalline material, the word lines WL0 and WL1 may also be mono-crystalline in their composition.

Device isolation regions (not shown) may be formed in the substrate 110, and second type impurities electrically opposite the first type impurities and different from that of the substrate 110 may be implanted between the device isolation regions to form the word lines WL0 and WL1.

A vertical cell diode Dp may be formed on each of the word lines WL0 and WL1. That is, as illustrated in FIG. 3, a vertical cell diode Dp may be disposed within a second mold layer 130 (as another example of an insulating layer) formed on the first mold layer 120. Like the first mold layer 120, the second mold layer 130 may be formed from (e.g.,) SiOx. However, embodiments of the inventive concept are not limited thereto. For example, in certain embodiments of the inventive concept, the second mold layer 130 may be made of SiNx such as SiN or SiON.

The vertical cell diode Dp may include a first semiconductor pattern 132 and a second semiconductor pattern 134. To store data in each of the unit cells Cpl-1 and Cpl-2, the vertical cell diode Dp causes a write current applied through a corresponding one of the bit lines BL0 and BL1 to flow in a direction from the first electrode 145 to the second electrode 311. The first semiconductor pattern 132 and the second semiconductor pattern 134 may be formed by doping certain materials with impurities having different conductivity types. For example, when the first semiconductor pattern 132 has a first conductivity type (e.g., an N type), the second semiconductor pattern 134 may have a second conductivity type (e.g., a P type).

The first semiconductor pattern 132 may have a lower impurity concentration than the word lines WL0 and WL1. In addition, the impurity concentration of the second semiconductor pattern 134 may be higher than that of the first semiconductor pattern 132. The first and second semiconductor patterns 132 and 134 may be epitaxial layers. In this case, the first and second semiconductor patterns 132 and 134 may be mono-crystalline, just like the word lines WL0 and WL1.

The first electrode 145 is disposed on the vertical cell diode Dp. The first electrode 145 may be disposed within a contact hole 141 which is formed in a first inter-layer insulating film 140. Like the first mold layer 120, the first interlayer insulating film 140 may be made of SiOx. However, embodiments of the inventive concept are not limited thereto. The first interlayer insulating film 120 may also be made of SiNx such as SiN or SiON.

The first electrode 145 may be made of a material such as TiN, TiAIN, TaN, WN, MoN, NbN, TiSiN, TiBN, ZrSiN, WSiN, WBN, ZrAIN, MoAIN, TaSiN, TaAIN, TiW, TiAl, TiON, TiAION, WON, or TaON. The first electrode 145 may contain a first material which forms the body of the first electrode 145 and a second material which is produced by a chemical reaction between the first material and an etchant or an oxidizing agent during the formation of the first electrode 145. For example, when the first electrode 145 is made of TiN, the first material that forms the body of the first electrode 145 may be TiN, and the second material that is produced by a chemical reaction between TiN and the oxidizing agent may be TiON. That is, the first electrode 145 may contain TiN as the first material and TiON as the second material. The first material contained in the first electrode 145 may be any one of the materials listed above.

The phase-change material pattern 211 is disposed on the first electrode 145. The phase-change material pattern 211 may be made of a combination of two elements such as GaSb, InSb, InSe, SbTe or GeTe, a combination of three elements such as GeSbTe, GeBiTe, GaSeTe, InSbTe, SnSb₂Te₄ or InSbGe, or a combination of four elements such as AgInSbTe, (GeSn)SbTe, GeSb(SeTe) or Te₈₁Ge₁₅Sb₂S₂. These materials may also be doped with N, Si, C, or O to improve semiconductor characteristics of the phase-change material pattern 211. For example, the phase-change material pattern 211 may be made of GeSbTe doped with N, Si, C or O.

The second electrode 311 is disposed on the phase-change material pattern 211. The second electrode 311 may be made of the same material as the first electrode 145. However, embodiments of the inventive concept are not limited thereto. A representative example of the material that forms the second electrode 311 may be Ti/TiN.

Although not shown in FIG. 3, bit lines (not shown) may be formed on the second electrode 311. The bit lines may intersect in an overlapping manner the word lines WL0 and WL1 and may be made of a material such as Al or W.

A method of fabricating the semiconductor device according to an embodiment of the inventive concept will now be described with reference to FIGS. 3 through 11. FIGS. 4 through 11 are related cross-sectional views respectively illustrating processes included within the method of fabricating the semiconductor device according to the embodiment of the inventive concept shown in FIG. 3.

Referring to FIG. 4, the first mold layer 120 is formed on the substrate 110, and the first aperture 121 is selectively formed in the first mold layer 120 using a conventional photolithography process. Here, the first mold layer 120 may be formed of, e.g., silicon oxide by a chemical vapor deposition (CVD) process.

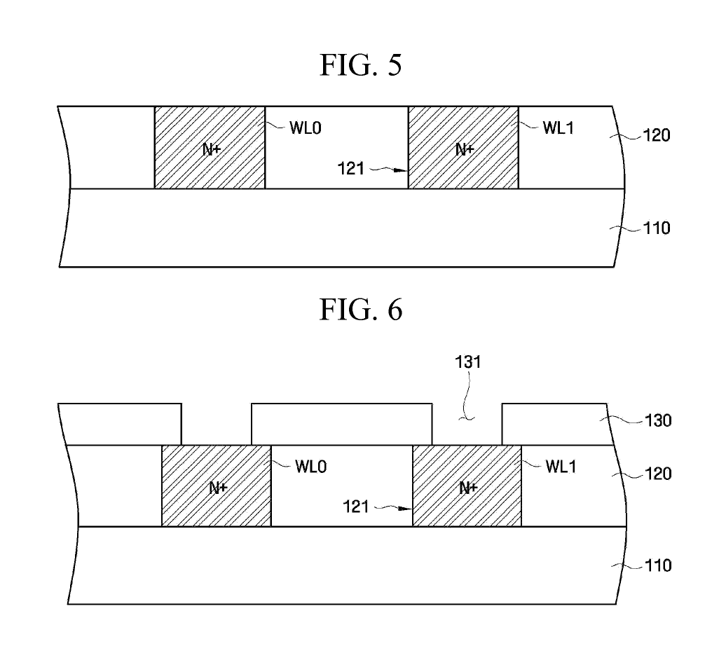

Next, referring to FIG. 5, each of the word lines WL0 and WL1 is formed in the first aperture 121. Specifically, each of the word lines WL0 and WL1 may be grown using a selective epitaxial growth (SEG) method and using a portion of the semiconductor substrate 110, which is exposed through the first aperture 121, as a seed layer. Here, when the semiconductor substrate 110 is mono-crystalline, a plurality of grown epitaxial layers are also mono-crystalline in composition. The word lines WL0 and WL1 may also be formed using a solid phase epitaxial (SPE) method. In this case, the conductor layers are planarized to expose a top surface of the first mold layer 120, thereby completing the word lines WL0 and WL1.

Next, referring to FIG. 6, the second mold layer 130 having a second aperture 131 is formed on the resultant structure of FIG. 5. The second mold layer 130 may be formed in the same manner as the first mold layer 120. However, embodiments of the inventive concept are not limited thereto.

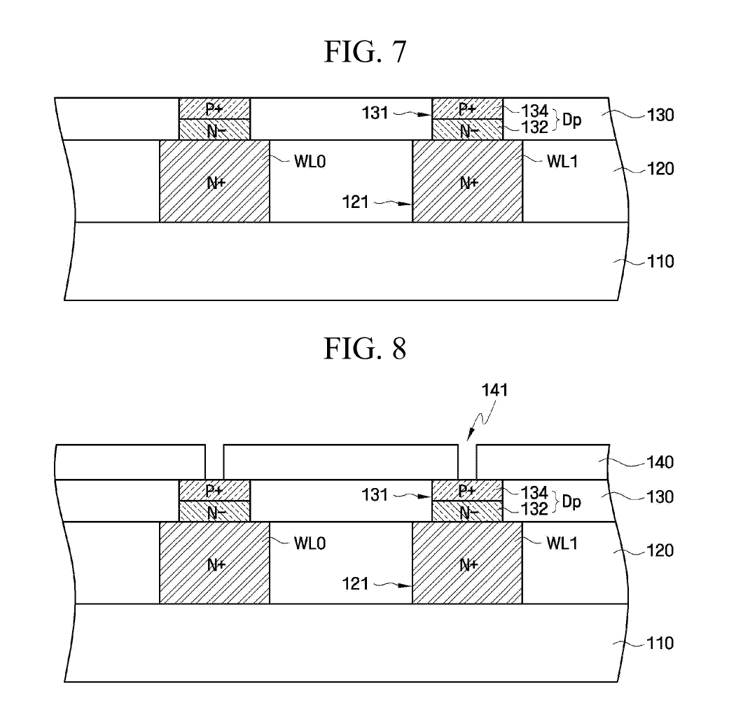

Next, referring to FIG. 7, the first and second semiconductor patterns 132 and 134 are sequentially formed in the second aperture 131 of the resultant structure of FIG. 6, thereby forming the vertical cell diode Dp.

The first and second semiconductor patterns 132 and 134 may be formed using various methods. For example, the first and second semiconductor patterns 132 and 134 may be grown using the SEG method. Specifically, the first semiconductor pattern 132 may be grown using each word line WL0 or WL1, which is exposed by the first aperture 121, as a seed layer, and the second semiconductor pattern 134 may be grown using the first semiconductor pattern 132 as a seed layer. Here, when the word lines WL0 and WL1 are mono-crystalline, the grown first and second semiconductor patterns 132 and 134 are also mono-crystalline ion composition.

Alternatively, the first and second semiconductor patterns 132 and 134 may be formed using the SPE method. Then, impurities of second conductivity type (e.g., the N type) may be ion-implanted into the first semiconductor pattern 132, and impurities of first conductivity type (e.g., the P type) may be ion-implanted into the second semiconductor pattern 134. While being grown using the SEC or SPE method, if the first and second semiconductor patterns 132 and 134 are doped in-situ with impurities, the ion-implantation process may be omitted.

Referring to FIG. 8, the first interlayer insulating film 140 having the contact hole 141 exposing a portion of the second semiconductor pattern 134 is formed on the resultant structure of FIG. 7. Here, the first interlayer insulating film 140 may be formed of (e.g.,) silicon oxide using a CVD process. The contact hole 141 may be formed using a conventionally understood photolithography process making use of a photoresist, for example.

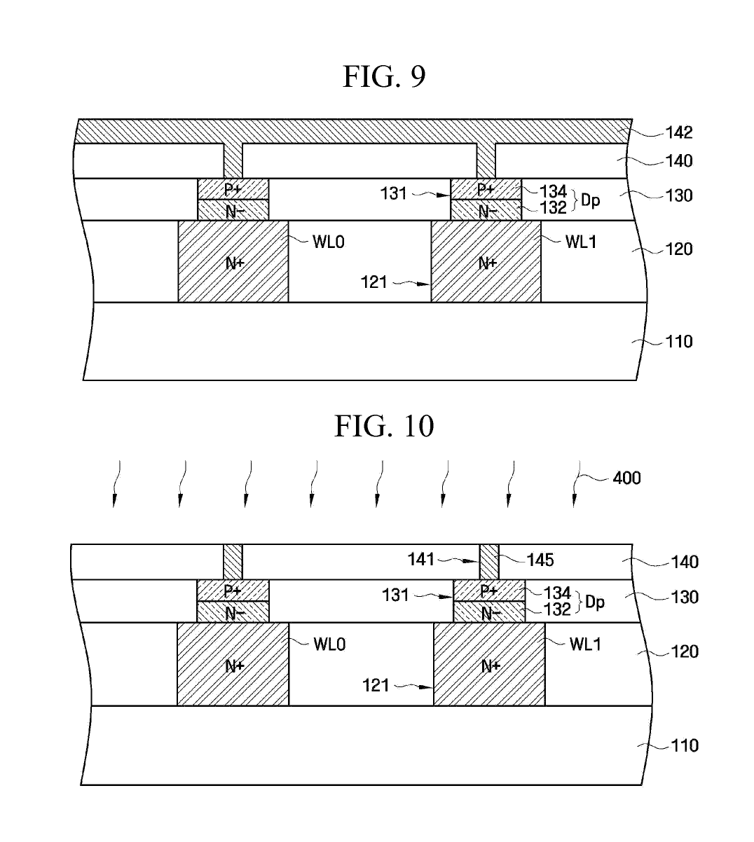

Referring to FIG. 9, a conductive layer 142 containing a first material is formed on the resultant structure of FIG. 8. Examples of the first material include TiN, TiAIN, TaN, WN, MoN, NbN, TiSiN, TiBN, ZrSiN, WSiN, WBN, ZrAIN, MoAIN, TaSiN, TaAIN, TiW, TiAl, TiON, TiAlON, WON, and TaON. That is, the conductive layer 142 may be formed of (e.g.,) TiN using a sputtering process, for example. Alternatively, the conductive layer 142 may be formed of TiN using a physical vapor deposition (PVD), CVD, or atomic layer deposition (ALD) process.

Referring to FIG. 10, the conductive layer 142 is planarized using (e.g.,) a chemical mechanical planarization (CMP) process. As a result, an upper portion of the conductive layer 142 formed on the first interlayer insulating film 140 is removed, and a residual portion of the conductive layer 142 remains within the contact hole 141 to form the first electrode 145. An oxidizing agent is used during the planarization process to planarize the conductive layer 142. Thus, a first portion of the first material used to form the conductive layer 142 reacts with the oxidizing agent, and the first electrode 145 formed by the planarization of the conductive layer 142 comprises in addition to the first material of conductive layer 142, a second material produced by the chemical reaction between the first portion of the first material and the oxidizing agent. Accordingly, the first electrode 145 comprises the first material and the second material.

When the conductive layer 142 is made of (e.g.,) TiN, the so-called first material using the nomenclature above is clearly TiN. Accordingly, the first electrode 145 also comprises the so-called second material, or an oxidized version of the first material which in this case is the TiON produced by a chemical reaction between TiN and the oxidizing agent.

The first and second materials forming the first electrode 145 are thus provided by the planarization of the conductive layer 142 in the presence of an oxidizing agent and may affect the relative concentration and/or distribution of the first and second materials forming the final structure of the first electrode 145.

The second material forming the first electrode 145 is more generally provided towards an upper surface of the first electrode 145. This is because the chemical reaction between the first material and the oxidizing agent occurs more actively toward the upper surface of the first electrode 145, which may be more exposed to an applied electrical field during the planarization process than the lower surface of the first electrode 145, which is relatively less exposed to the applied electrical external field.

Of note, the total concentration of the first material forming the first electrode 145 may be greater than that of the second material. However, the relative concentration of the second material forming the first electrode 145 may be greater than that of the first material towards the upper surface of the first electrode 145, since the chemical reaction between the first material and the oxidizing agent occurs more actively towards the upper surface of the first electrode 145.

As described above, the second material of the first electrode 145 is relatively more concentrated towards the upper surface of the first electrode 145. And in a subsequent process, the phase-change material pattern 211 is formed on the upper surface of the first electrode 145. Thus, the phase-change material pattern 211 contacts the upper surface of the first electrode 145. Here, since the concentration of the second material in the upper surface of the first electrode 145 is greater than the concentration of the first material, a contact resistance variation between the first electrode 145 and the phase-change material pattern 211 may defined. That is, the contact resistance between the resulting first electrode 145 and the phase-change material pattern 211 may be relatively high and may easily stray outside of the narrowly defined range of acceptable values. The resulting non-uniformity of contact resistances between the first electrode and the phase-change material of individual nonvolatile memory cells presents an unacceptable operating parameter. Indeed, increased non-uniformity in the contact resistances between the first electrode 145 and the phase-change material 221 may cause the phase(s) of the phase-change memory cells (e.g., the unit cells Cp-1 and Cp-2) subsequently formed on the substrate 110 to change in a non-uniform manner in response to a defined write current. In other words, even if data corresponding to logic value of ‘1’ (or a logic value of ‘0’) is stored in each of the unit cells Cpl-1 and Cp1-2 (i.e., phase-change memory cells) according to a defined write current, the resulting read margins for the respective unit cells Cpl-1 and Cp1-2 may be reduced by the increased (and varied) resistance inherent in the respective unit cells Cpl-1 and Cp1-2. In this regard, the second material of the first electrode 145 must be removed before the formation of the phase-change material pattern 211.

Referring to FIG. 10, the first electrode 145 is plasma-treated with plasma 400 of a gas having a molecular weight of 17 or less.

The gas may be a relatively chemically stable material. The reason why the gas having a molecular weight of 17 or less is used is to minimize damage to the first interlayer insulating film 140 during the plasma treatment of the first electrode 145. In addition, the reason why the gas should be a relatively chemically stable material is to prevent undesired side reactions between the gas and the first interlayer insulating film 140.

The gas used to form the plasma (hereafter, the “plasma gas”) may include at least one gas selected from the group consisting of He, H₂, Ne, and CH₄. However, embodiments of the inventive concept are not limited to only these plasma gases. Any plasma gas may be used as long as its molecular weight is 17 or less and it is relatively chemically stable material as described above.

The plasma gas may be activated to a plasma state 400 using direct current (DC) or applied radio frequency (RF) power. Then, an electrical voltage bias is applied to the activated plasma gas to thereby accelerate the activated plasma gas towards the first electrode 145.

As a result, the second material forming the first electrode 145 is removed. Accordingly, the concentration of the second material in the first electrode 145 changes due to the applied plasma-treatment process. That is, the concentration of the second material in the upper surface of the first electrode 145 is reduced by the plasma-treatment process. More specifically, after plasma treatment of the first electrode 145, the concentration of the second material in the first electrode 145 may markedly reduced relative to the first material, particularly in the upper surface of the first electrode 145.

Since the concentration of the second material in the upper surface of the first electrode 145 is reduced by the plasma-treatment process, an increase in the contact resistance variation between the first electrode 145 and the phase-change material pattern 211 may be prevented. The plasma-treatment process may be performed in-situ within the same chamber as the chamber used to form the first electrode 145.

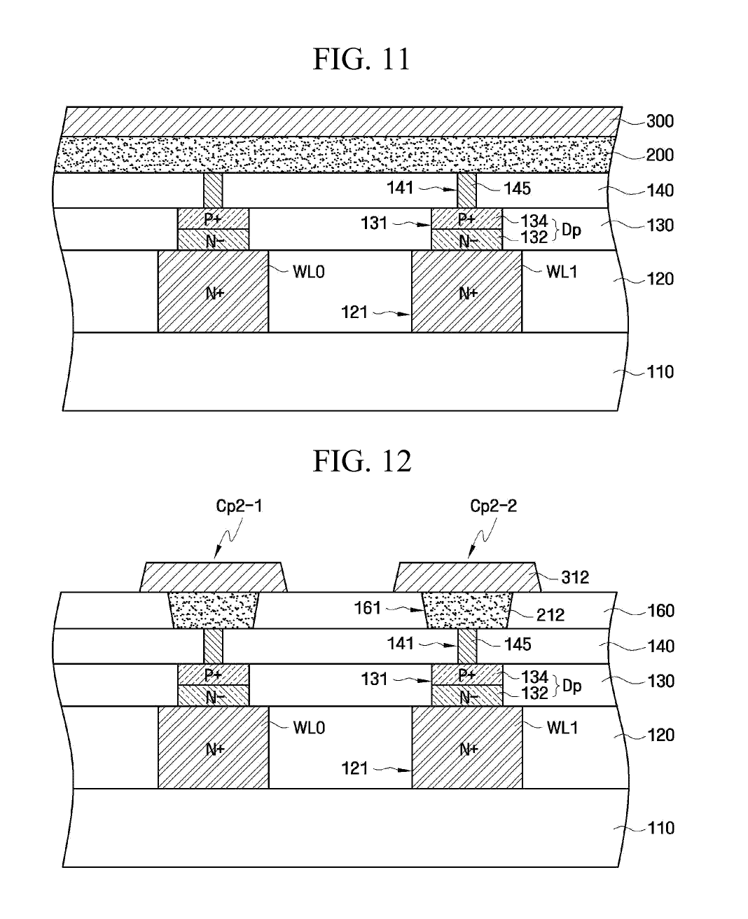

Next, referring to FIG. 11, a phase-change material film 200 is formed on the resultant structure of FIG. 10. Here, the phase-change material film 200 may be formed by a CVD, ALD, or PVD process. The phase-change material film 200 may be made of GeSbTe, C-doped GeSbTe, or N-doped GeSbTe.

Next, a conductive film 300 is formed on the phase-change material film 200. The conductive film 300 may be a double film of, e.g., Ti/TiN. The conductive film 300 may be formed using a CVD or PVD process.

The phase-change material film 200 and the conductive film 300 are patterned to form the phase-change material pattern 211 and the second electrode 311 as shown in FIG. 3. Although not shown in the drawings, the bit lines BL0 and BL1 may be formed on the second electrode 311 to intersect the word lines WL0 and WL1.

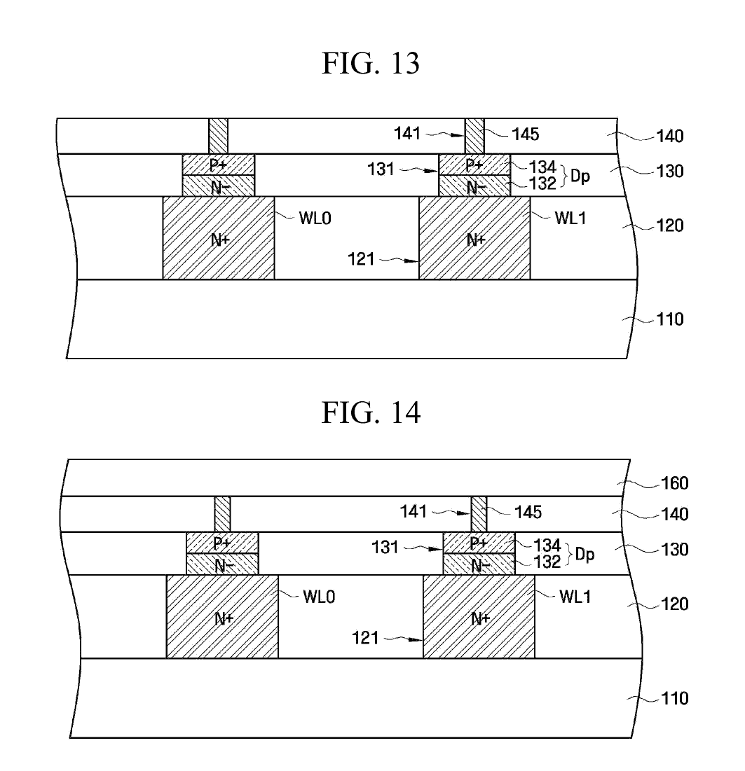

Hereinafter, a method of fabricating a semiconductor device according to another embodiment of the inventive concept will be described with reference to FIGS. 7 and 12 through 17. FIG. 12 is a cross-sectional view of a semiconductor device fabricated according this embodiment of the inventive concept. FIGS. 13 through 17 are related cross-sectional views respectively illustrating processes included within a method of fabricating the semiconductor device according to this embodiment of the inventive concept. For the sake of simplicity, elements similar to those previously described in relation to the embodiment of FIG. 3 will be similarly labeled, but their detailed description will not be repeated.

Referring to FIG. 12, the semiconductor device fabricated according to another embodiment of the inventive concept is substantially the same as the semiconductor device (shown in FIG. 3) fabricated according to the previous embodiment, except that a phase-change material pattern 212 is formed using a damascene process.

Referring to FIG. 13, a first interlayer insulating film 140 is formed on the resultant structure of FIG. 7, and a contact hole 141 is formed. Then, a conductive layer (not shown) containing a first material is formed on the first interlayer insulating film 140 and is then planarized to form a first electrode 145. The first electrode 145 may contain a second material that is produced by a chemical reaction between the first material and an oxidizing agent during the planarization of the conductive layer. The concentration distributions of the first and second materials in the first electrode 145 fabricated according to the subject embodiment are substantially the same as those in the first electrode 145 fabricated according to the previous embodiment, and thus a redundant description thereof will be omitted.

Referring to FIG. 14, a second interlayer insulating film 160 is formed on the first interlayer insulating film 140. The second interlayer insulating film 160 may be formed of, e.g., silicon oxide by a CVD process.

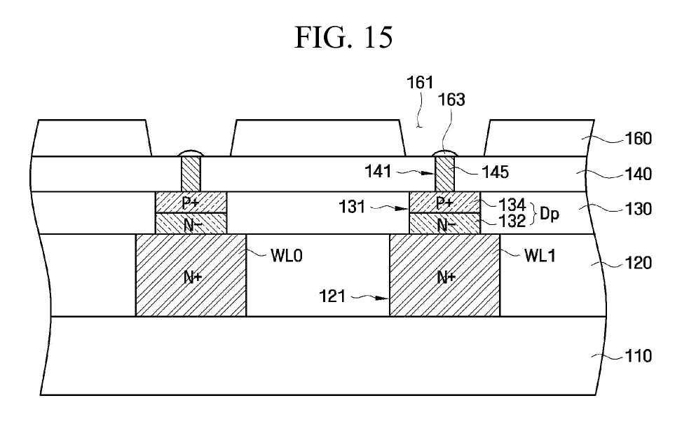

Next, referring to FIG. 15, a via hole 161 is formed in the second interlayer insulating film 160 to expose the first electrode 145. The via hole 161 may be formed by a photolithography process using a photoresist.

To form the via hole 161, a selected portion of the second interlayer insulating film 160 is etched. As the second interlayer insulating film 160 is etched, a portion of the material contained in the second interlayer insulating film 160 may be stacked on the first electrode 145, thereby forming a restacked film 163. Together with the second material forming the first electrode 145, the restacked film 163 formed on the first electrode 145 may increase the contact resistance variation between the first electrode 145 and the phase-change material pattern 212.

Accordingly, this may increase the non-uniformity in the contact resistance of the first electrode 145, thereby causing the phase(s) of all of the phase-change memory cells (e.g., Cp2-1 and Cp2-2) which are to be formed on a substrate 110 during in a subsequent process to change in a non-uniform manner in response to a certain write current. In other words, even if data corresponding to logic value ‘1’ (or logic value ‘0’) is stored in each of the phase-change memory cells Cp2-1 and Cp2-2 by applying a certain write current to each of the phase-change memory cells Cp2-1 and Cp2-2, the resulting read margin may be reduced by the increased resistance variations of the phase-change memory cells Cp2-1 and Cp2-2. In this regard, the restacked film 163 on the first electrode 145 and the second material of the first electrode 145 must be removed before the formation of the phase-change material pattern 212.

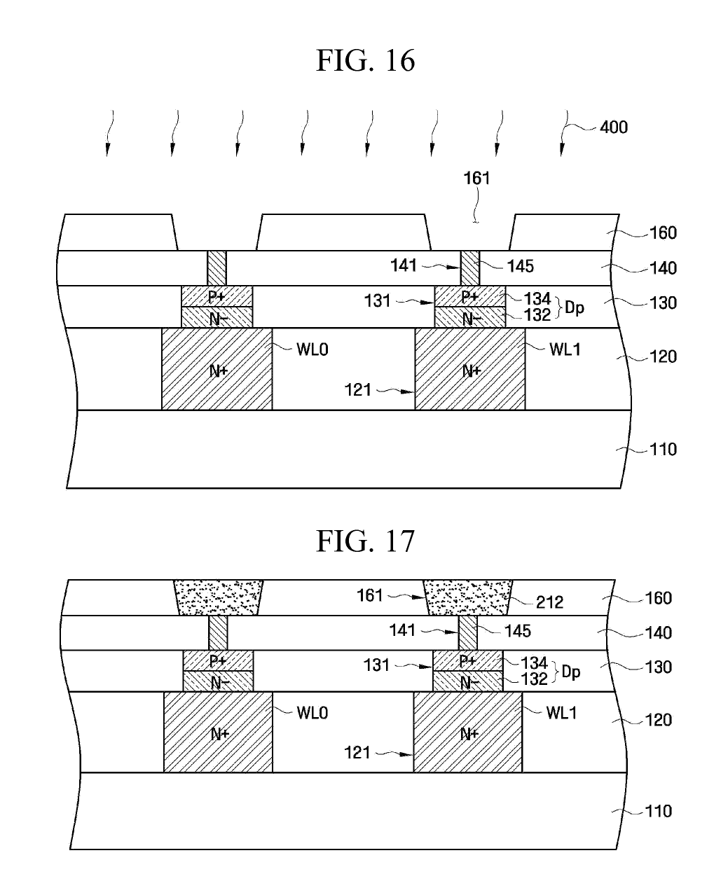

Next, referring to FIG. 16, the first electrode 145 is plasma-treated with plasma 400 using a plasma gas having a molecular weight of 17 or less. The plasma 400 may be substantially the same as the above-described plasma 400, and thus a redundant description thereof will be omitted.

As before, an electrical bias is applied to the activated plasma gas to thereby accelerate the activated plasma gas towards the first electrode 145.

As a result, the restacked film 163 on the first electrode 145 is removed. In addition, the concentration of the second material in the first electrode 145 changes due to the applied plasma treatment. That is, the concentration of the second material in the first electrode 145 is reduced due to the applied plasma-treatment process. More specifically, after the plasma treatment of the first electrode 145, the concentration of the second material in the first electrode 145 is markedly reduced particularly in the upper surface portion of the first electrode 145.

Since the restacked film 163 formed on the first electrode 145 is removed and the concentration of the second material in the upper surface of the first electrode 145 is reduced due to the applied plasma-treatment process, an increase in the contact resistance variation between the first electrode 145 and the phase-change material pattern 212 may be prevented.

Referring to FIG. 17, a phase-change material film (not shown) is formed in the via hole 161 and on the second interlayer insulating film 160. Then, the phase-change material film (not shown) is planarized to form the phase-change material pattern 212 in the via hole 161.

Next, a conductive film (not shown) is formed on the phase-change material film. The conductive film may be a double film of, e.g., Ti/TiN and may be formed using a CVD or PVD process. The conductive film is patterned to form a second electrode 312 on the phase-change material pattern 212 as shown in FIG. 12. Although not shown in the drawings, bit lines BL0 and BL1 may be formed on the second electrode 312 to intersect word lines WL0 and WL1.

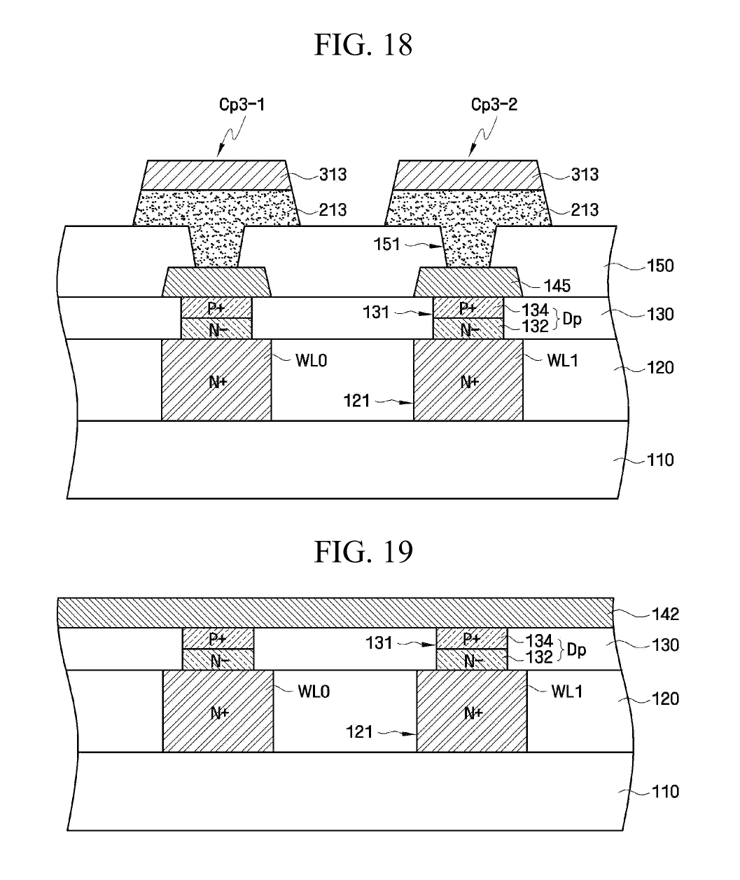

Hereinafter, a method of fabricating a semiconductor device according to yet another embodiment of the inventive concept will be described with reference to FIGS. 7 and 18 through 24. FIGS. 18 through 24 are related cross-sectional views respectively illustrating processes included within a method of fabricating a semiconductor device. As before, for the sake of simplicity, similar elements are similarly designated and their detailed descriptions are not repeated.

Referring to FIG. 19, a conductive layer 142 containing a first material is formed on the resultant structure of FIG. 7. The conductive layer 142 may be formed of the same material and in the same manner as the conductive layer 142 previously described.

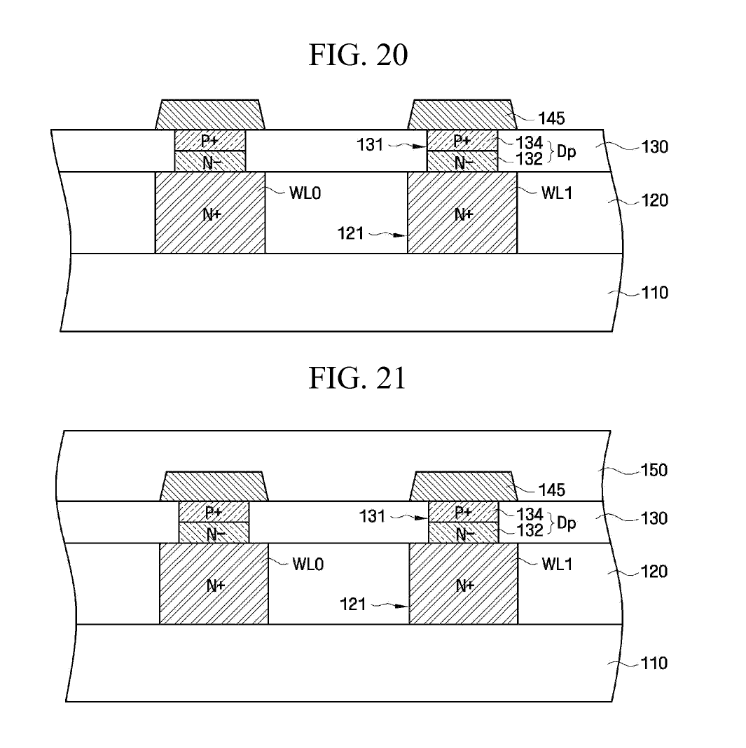

Next, referring to FIG. 20, the conductive layer 142 may be patterned to form a shaped first electrode 145. When the conductive layer 142 is patterned, one or more conventionally understood etchants may be used. Here, the first material forming the conductive layer 142 chemically reacts with the etchant(s), thereby producing a second material. Accordingly, the shaped first electrode 145 comprises, as before, both the first material and the second material. The concentration distributions of the first and second materials in the first shaped electrode 145 fabricated in this manner may be substantially the same as those in the first electrode 145 fabricated according to the previous embodiments, and thus a redundant description thereof will be omitted.

Referring to FIG. 21, an interlayer insulating film 150 is formed on the resultant structure of FIG. 20. The interlayer insulating film 150 may be formed of, e.g., silicon oxide by a CVD process.

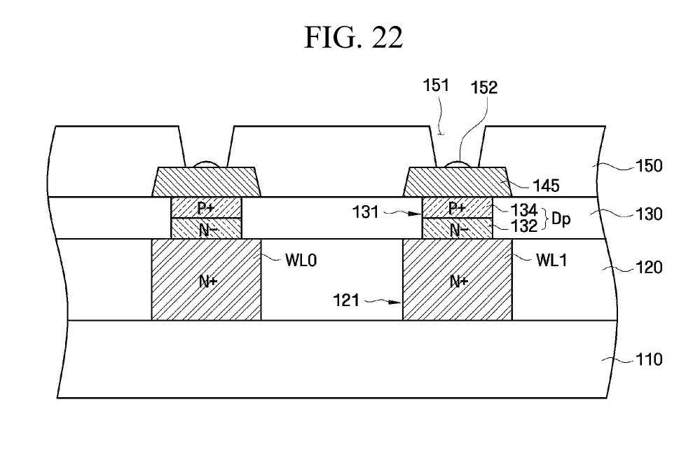

Next, referring to FIG. 22, a via hole 151 is formed in the interlayer insulating film 150 to expose the first shaped electrode 145. The via hole 151 may be formed by a photolithography process using a photoresist.

To form the via hole 151, a portion of the interlayer insulating film 150 is selectively etched. As the interlayer insulating film 150 is selectively etched, some residual portion of the material forming the interlayer insulating film 150 may become stacked on the first electrode 145, thereby forming a restacked film 152. Together with the second material forming the first electrode 145, the restacked film 152 formed on the first shaped electrode 145 may increase the contact resistance variation between the first shaped electrode 145 and a phase-change material pattern 213.

This may increase the non-uniformity in the contact resistance of the first electrode 145, thereby causing the phase(s) of all of the phase-change memory cells Cp3-1 and Cp3-2, which are to be formed on a substrate 110 in a subsequent process, to change in a non-uniform manner in response to a certain write current. In other words, even if data corresponding to logic value ‘1’ (or logic value ‘0’) is stored in each of the phase-change memory cells Cp3-1 and Cp3-2 by supplying a certain write current to each of the phase-change memory cells Cp3-1 and Cp3-2, a read margin may be reduced by the increased resistance variations of the phase-change memory cells Cp3-1 and Cp3-2. In this regard, the restacked film 152 on the first electrode 145 and the second material of the first shaped electrode 145 must be removed before the formation of the phase-change material pattern 213.

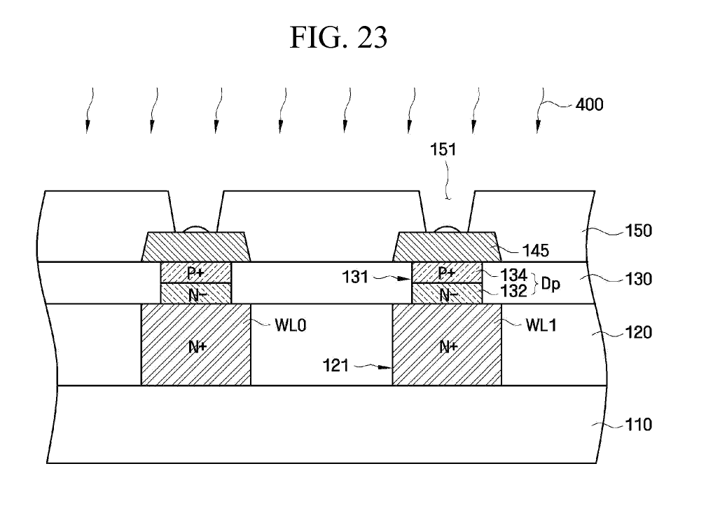

Next, referring to FIG. 23, the first electrode 145 is plasma-treated with plasma 400 of a gas having a molecular weight of 17 or less. The plasma 400 may be substantially the same as the above-described plasma 400 and thus a redundant description thereof will be omitted.

As before, an electrical bias voltage is applied to the activated plasma gas to thereby accelerate the activated plasma gas towards the first shaped electrode 145.

As a result, the restacked film 152 remaining on the first shaped electrode 145 is removed. In addition, the concentration of the second material in the first shaped electrode 145 changes after the plasma treatment of the first shaped electrode 145. That is, the concentration of the second material in the first shaped electrode 145 is reduced after the plasma-treatment process. More specifically, after the plasma treatment of the first shaped electrode 145, the concentration of the second material in the upper surface of the first shaped electrode 145 may be markedly reduced.

Since the restacked film 152 on the first shaped electrode 145 is removed and the concentration of the second material in the upper surface of the first shaped electrode 145 is reduced due to the applied plasma-treatment process, an increase in the contact resistance variation between the first electrode 145 and the phase-change material pattern 213 may be prevented.

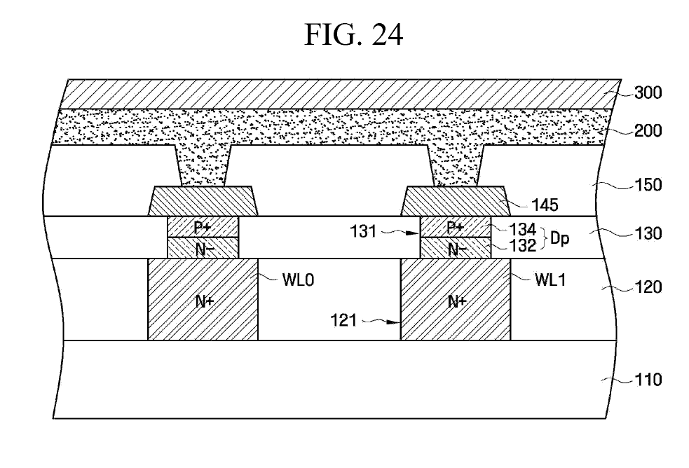

Referring to FIG. 24, a phase-change material film 200 is formed on the resultant structure of FIG. 23. The phase-change material film 200 may be formed by a CVD, ALD, or PVD process. Here, the phase-change material film 200 may be made of GeSbTe, C-doped GeSbTe, or N-doped GeSbTe.

Next, a conductive film 300 is formed on the phase-change material film 200. The conductive film 300 may be a double film of, e.g., Ti/TiN and may be formed using a CVD or PVD process.

Then, the phase-change material film 200 and the conductive film 300 are patterned to form the phase-change material pattern 213 and a second electrode 313 as shown in FIG. 18. Although not shown in the drawings, bit lines BL0 and BL1 may be formed on the second electrode 313 to intersect word lines WL0 and WL1.

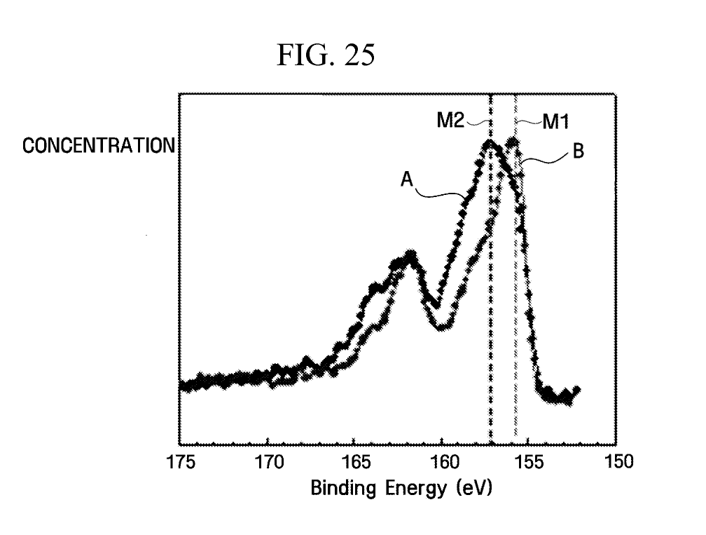

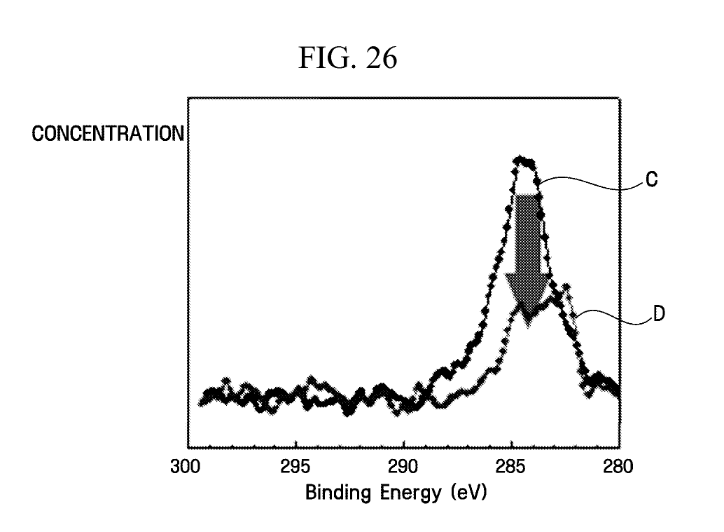

Characteristics of a first electrode provided in a semiconductor device according to embodiments of the inventive concept will now further be described with reference to FIGS. 25 and 26. FIG. 25 is a graph illustrating a difference in the concentrations of first and second materials in the upper surface of a first electrode both before and after the applied plasma treatment. FIG. 26 is a graph illustrating a difference in the concentration of oxygen in a first electrode between before and after the plasma treatment of the first electrode.

Referring to FIG. 25, a curve ‘A’ represents the concentrations of a first material Ml and a second material M2 in the upper surface of a first electrode 145 (see FIG. 3) before the plasma treatment of the first electrode 145, and a curve ‘B’ represents the concentrations of the first and second materials Ml and M2 in the surface of the first electrode 145 after the plasma treatment of the first electrode 145.

The first electrode 145 may be formed as follows. That is, a conductive layer 142 (see FIG. 9) containing the first material M1 is formed on a first interlayer insulating film 140 (see FIG. 9) and is then planarized using a CMP process. Here, the first material Ml of the conductive layer 142 may chemically react with an oxidizing agent used in the CMP process, thereby producing the second material M2. Accordingly, the first electrode 145 may contain the first material M1 and the second material M2. The first electrode 145 is plasma-treated with plasma of a mixed gas of H₂ and He.

Here, the first material Ml may be TiN, and the oxidizing agent used in the CMP process may be H₂O₂. In addition, the second material M2 produced by the chemical reaction between TiN and H₂O₂ may be TiON. In addition, the binding energy of TiN, which is the first material M1, is approximately 155.8 eV, and the binding energy of TiON, which is the second material M2, is approximately 157 eV.

Referring to the curve A of FIG. 25, the concentration of TiON (i.e., the second material M2) having a binding energy of approximately 157 eV is higher than that of TiN (i.e., the first material M1) having a binding energy of approximately 155.8 eV. That is, the concentration of the second material M2 in the surface of the first electrode 145 is higher than that of the first material M1 before the plasma treatment of the first electrode 145.

Referring to the curve B of FIG. 25, the concentration of TiN (i.e., the first material M1) having a binding energy of approximately 155.8 eV is higher than that of TiON (i.e., the second material M2) having a binding energy of approximately 157 eV. That is, the concentration of the first material M1 in the surface of the first electrode 145 is higher than that of the second material M2 after the plasma treatment of the first electrode 145. Therefore, it can be understood that the plasma-treatment process removes the second material M2 of the first electrode 145. Accordingly, the concentration of the second material M2 in the surface of the first electrode 145 is reduced, thereby preventing an increase in the contact resistance variation between the first electrode 145 and a phase-change material pattern 211 (see FIG. 3).

Referring to FIG. 26, a curve ‘C’ represents the concentration of oxygen in the first electrode 145 before the plasma-treatment process, and a curve ‘D’ represents the concentration of oxygen in the first electrode 145 after the plasma-treatment process. As is apparent from FIG. 26, the concentration of oxygen in the first electrode 145 is reduced after the plasma treatment of the first electrode 145. The reduced concentration of oxygen in the first electrode 145 prevents an increase in the contact resistance variation between the first electrode 145 and the phase-change material pattern 211.

While the inventive concept has been particularly shown and described with reference to exemplary embodiments thereof, it will be understood by those of ordinary skill in the art that various changes in form and detail may be made therein without departing from the scope of the inventive concept as defined by the following claims. The exemplary embodiments should be considered in a descriptive sense only and not for purposes of limitation.

What is claimed is:

1. A method of fabricating a semiconductor device, the method comprising:
forming an insulating layer on a semiconductor substrate;
forming a contact hole in the insulating layer;
forming a conductive layer comprising a first material, wherein the conductive layer comprises a first portion formed in the contact hole and a second portion formed on the insulating layer;
planarizing the conductive layer in the presence of an oxidizing agent to remove the second portion of the conductive layer from the insulating layer, wherein a portion of the first material is changed to a second material by the presence of the oxidizing agent, such that a first electrode is formed by the first portion of the conductive layer comprising both the first material and the second material;
plasma-treating the first electrode with a plasma formed from a plasma gas having a molecular weight of 17 or less to reduce a concentration of the second material in the first electrode relative to a concentration of the first material; and
forming a phase-change material pattern on the first electrode.

2. The method of claim 1, wherein during the planarizing of the conductive layer the concentration of the second material in the first electrode increases towards an upper surface of the first electrode.

3. The method of claim 2, wherein following the planarizing of the conductive layer to form the first electrode the concentration of the second material in the upper surface of the first electrode is greater than the concentration of the first material.

4. The method of claim 1, wherein the plasma gas comprises at least one gas selected from a group of gases consisting of He, H₂, Ne, and CH₄.

5. The method of claim 1, wherein the planarizing of the conductive layer is performed using a chemical mechanical planarization (CMP) process.

6. The method of claim 1, further comprising forming a second electrode on the phase-change material pattern.

7. A method of fabricating a semiconductor device, the method comprising:
forming a first insulating layer on a semiconductor substrate;
forming a contact hole in the first insulating layer;
forming a conductive layer comprising a first material, wherein the conductive layer comprises a first portion formed in the contact hole and a second portion formed on the first insulating layer;
planarizing the conductive layer in the presence of an oxidizing agent to remove the second portion of the conductive layer from the first insulating layer, wherein a portion of the first material is changed to a second material by the presence of the oxidizing agent, such that a first electrode is formed by the first portion of the conductive layer comprising both the first material and the second material;
forming a second insulating layer on the first insulating layer including the first electrode;
forming a via hole in the second insulating layer to expose an upper surface of the first electrode, wherein forming the via hole in the second insulating layer causes the formation of a residual restacked film on the upper surface of the first electrode;
plasma-treating the upper surface of the first electrode exposed through the via hole with a plasma formed from a plasma gas having a molecular weight of 17 or less to remove the residual restacked film and reduce a concentration of the second material in the first electrode relative to a concentration of the first material; and
forming a phase-change material pattern on the first electrode.

8. The method of claim 7, wherein during the planarizing of the conductive layer the concentration of the second material in the first electrode increases towards the upper surface of the first electrode.

9. The method of claim 8, wherein following the planarizing of the conductive layer the concentration of the second material in the upper surface of the first electrode is greater than the concentration of the first material.

10. The method of claim 7, wherein the plasma gas comprises at least one gas selected from a group of gases consisting of He, H₂, Ne, and CH₄.

11. The method of claim 7, wherein the planarizing of the conductive layer is performed using a chemical mechanical planarization (CMP) process.

12. The method of claim 11, wherein the oxidizing agent is water.

13. The method of claim 7, further comprising forming a second electrode on the phase-change material pattern.

14. A method of fabricating a nonvolatile semiconductor memory device, the method comprising:
forming a first mold layer on a semiconductor substrate, forming a first aperture in the first mold layer, and forming a word line in the first aperture;
forming a second mold layer on the first mold layer including the word line, forming a second aperture in the second mold layer, and forming a vertical diode in the second aperture;
forming a first interlayer insulating layer on the second mold layer including the vertical diode and forming contact hole in the first interlayer insulating layer;
forming a conductive layer comprising a first material on the first interlayer insulating layer, wherein the conductive layer comprises a first portion formed in the contact hole and a second portion formed on the first interlayer insulating layer;
planarizing the conductive layer in the presence of an oxidizing agent to remove the second portion of the conductive layer from the first interlayer insulating layer, wherein a portion of the first material is changed to a second material by the presence of the oxidizing agent such that the first electrode comprises both the first material and the second material;
plasma-treating the first electrode with a plasma formed from a plasma gas having a molecular weight of 17 or less to reduce a concentration of the second material in the first electrode relative to a concentration of the first material;
forming a phase-change material pattern on the first electrode; and
forming a second electrode on the phase-change material pattern.

15. The method of claim 14, wherein during the planarizing of the conductive layer the concentration of the second material in the first electrode increases towards an upper surface of the first electrode.

16. The method of claim 15, wherein following the planarizing of the conductive layer the concentration of the second material in the upper surface of the first electrode is greater than the concentration of the first material.

17. The method of claim 14, wherein the plasma gas comprises at least one gas selected from a group of gases consisting of He, H₂, Ne, and CH₄.

18. The method of claim 14, wherein the planarizing of the conductive layer is performed using a chemical mechanical planarization (CMP) process.

19. The method of claim 14, wherein the oxidizing agent is water.

20. The method of claim 14, wherein the phase-change material pattern is formed from at least one of germanium (Ge), antimony (Sb) and tellurium (Te).
